(19) United States
(12) Patent Application Publication
(10) Pub. No.: US 2010/0006560 A1
(43) Pub. Date: Jan. 14, 2010

(54) SUBSTRATE HEATING APPARATUS AND SUBSTRATE HEATING METHOD

(75) Inventors: Akihiro EGAMI, Kawasaki-shi (JP); Akira Kumagai, Kofu-shi (JP); Kenji Numajiri, Chofu-shi (JP); Mamami Shibagaki, Fuchu-shi (JP); Seiji Furuya, Minamitsuru-gun (JP)

Correspondence Address: BUCHANAN, INGERSOLL & ROONEY PC, POST OFFICE BOX 1404, ALEXANDRIA, VA, 22313-1404, US

(73) Assignee: CANON ANELVA CORPORATION, Kawasaki-shi (JP)

(21) Appl. No.: 12/562,178

(22) Filed: Sep. 18, 2009

Related U.S. Application Data
(63) Continuation of application No. PCT/JP2008/055128, filed on Mar. 19, 2008.

(30) Foreign Application Priority Data
Mar. 20, 2007 (JP) 2007-072960

(51) Int. Cl. H01L 21/30; H01L 21/324; H01J 37/20

(52) U.S. Cl. 219/430; 219/428; 219/436; 219/444.1

(57) ABSTRACT

In a substrate heating apparatus including a vacuum vessel with an interior separated by a wall body into a first space and a second space, the first space being evacuated to a vacuum by a first exhaust means and accommodating a substrate to be heated, and the second space being evacuated to a vacuum by a second exhaust means and including a heating means for heating the substrate accommodated in the substrate, the time required to evacuate the first space to a vacuum by the first exhaust means is shortened, thus improving the throughput. The wall body has a non-coating surface, which is not coated, on part of a wall body surface which faces the second space. A coating is formed on the remaining portion of the wall body surface.

### TECHNICAL FIELD

The present invention relates to a substrate heating apparatus which is made of graphite with a surface coated with pyrolytic carbon and heats a substrate in a vacuum atmosphere, and a method of heating a substrate using the substrate heating apparatus.

### BACKGROUND ART

Heating in a vacuum vessel in a substrate heating apparatus includes an external heating type which heats a substrate with a heat set outside the vacuum vessel, and an internal heating type with which a heater is arranged in the vacuum vessel.

Of the two types, in the external heating type, if the vacuum vessel is made of a metal, for example, stainless steel, it has a low thermal conductivity and an excessively wide temperature distribution. If the vacuum vessel is made of aluminum or copper, its emissivity is low and accordingly cannot transfer heat by radiation. Therefore, in the external heating type, the vacuum vessel is manufactured using graphite having a high emissivity and high thermal conductivity, so that it can have a uniform temperature distribution and good temperature rise/drop characteristics.

In the internal heating type, a technique is proposed in which a space where a substrate to be heated is accommodated and a space where a heating means is accommodated are separated by a wall body (see, e.g., patent reference 1). For example, this corresponds to a substrate heating apparatus 100 including a vacuum vessel as shown in FIG. 7.

In the substrate heating apparatus 100, a wall body 101 separates the vacuum vessel into a first space 102 and second space 103. The first space 102 is evacuated by a first exhaust means (not shown) to a vacuum as indicated by an arrow 104. A substrate 105 to be heated is loaded into and unloaded from the first space 102 by a substrate transport means (not shown) and accommodated in the first space 102 as shown in FIG. 7. The second space 103 is evacuated by a second exhaust means (not shown) to a vacuum as indicated by an arrow 106 and includes a heating means 107 for heating the substrate 105 accommodated in the first space 102.

The internal heating type substrate heating apparatus 100 can also have a uniform temperature distribution and good temperature rise/drop characteristics if the wall body 101 is made of graphite.

However, graphite is porous and occludes gas in its pores. If the wall body 101 which separates the vacuum vessel into the first space 102 for accommodating the substrate 105 to be heated and the second space 103 where the heating means 107 is arranged is manufactured using graphite, as described above, when the interior of the first space 102 of the vacuum vessel is set at the atmospheric pressure so that the substrate 105 heated in the vacuum atmosphere is to be extracted outside the vacuum vessel, the gas is occluded, via the pores, in the graphite which forms the wall body 101.

Therefore, even when the first space 102 and second space 103 of the vacuum vessel are evacuated to a vacuum as a preparation for heating the next substrate 105 in the vacuum atmosphere in the first space 102 of the vacuum vessel, the gas occluded in the graphite keeps emitted to the first space 102 and second space 103. As a result, vacuum evacuation of the interiors of the first space 102 and second space 103 of the vacuum vessel until they reach a vacuum degree required for substrate heating takes a long period of time.

In view of this, to eliminate the drawbacks described above of graphite which is porous and occludes gas via its pores, a technique has been proposed which coats the surface of the graphite with pyrolytic carbon or pyrolytic graphite to fill the pores, thus preventing gas molecule occlusion (for example, see patent reference 2).

As the pyrolytic carbon forms a high-purity, dense film, it fills the pores and prevents gas permeation. The pyrolytic carbon is also said to have a high mechanical strength and thus serves as a protection film for the vessel.

Patent Reference 1: International Publication WO 2006/043530

Patent Reference 2: Japanese Latent Laid-Open No. 2004-351285

### DISCLOSURE OF INVENTION

### Problems that the Invention is to Solve

The technique described in the above patent reference 2 is to coat, for example, the inner surface of an external heating type vacuum vessel made using pyrolytic carbon by, for example, chemical vapor deposition. This technique is assumed to prevent gas permeation and gas occlusion in the wall of a graphite vacuum vessel by utilizing the nature of pyrolytic carbon that the gas permeability is low.

In a heating apparatus used at a high temperature of about 2,000° C., however, when the total time during which the apparatus is used becomes long, repetitive temperature rises and drops form microscopic cracks in the surface of the coating, and the coating may deteriorate partially.

In this manner, even when the heating apparatus includes a vacuum vessel in which graphite is coated with pyrolytic carbon, the coating may gradually deteriorate due to microscopic cracks formed in the surface of the coating by repetitive temperature rises and drops.

The present invention has as its object to solve the problems described above in the heating apparatus includes the vacuum vessel in which graphite is coated with pyrolytic carbon. More specifically, it is an object of the present invention to provide a substrate heating technique which prevents deterioration of a coating by preventing microscopic cracks in a portion with a particularly large heat gradient of the coating surface of graphite that forms the vacuum vessel of a substrate heating apparatus, thus achieving structural stability of a wall body.

More specifically, it is an object of the present invention to provide a substrate heating apparatus including a vacuum vessel with an interior separated by a wall body into a first space and second space, the first space being evacuated to a vacuum by a first exhaust means and accommodating a substrate to be heated, and the second space being evacuated to a vacuum by a second exhaust means and including a heating means for heating the substrate accommodated in the substrate, and a method of heating a substrate by using the substrate heating apparatus.

### Means of Solving the Problems

In order to achieve the above object, according to the present invention, there is provided a substrate heating apparatus for heating a substrate, comprising a vacuum vessel with an interior separated by a wall body made of graphite with a surface coated with a coating material including a carbon atom into a first space which accommodates a substrate to be heated and a second space where heating means for heating the substrate accommodated in the first space is arranged,

wherein the wall body facing the second space includes a portion in which coating is formed on a surface of the wall body, and an exposed graphite portion in which coating is not formed on a surface of the wall body.

Alternatively, in order to achieve the above object, according to the present invention, there is also provided a substrate heating apparatus for heating a substrate, comprising a vacuum vessel with an interior separated by a wall body made of graphite with a surface coated with a coating material including a carbon atom into a first space which accommodates a substrate to be heated and a second space where heating means for heating the substrate accommodated in the first space is arranged,

wherein the wall body facing the first space includes an exposed graphite portion on a surface of the wall body surface.

According to the present invention, a substrate heating apparatus can be provided which can prevent deterioration of a coating by preventing microscopic cracks in the vacuum vessel of the substrate heating apparatus, so that the structural stability of a wall body can be improved.

### BRIEF DESCRIPTION OF DRAWINGS

The accompanying drawings, which are incorporated in and constitute a part of the specification, illustrate embodiments of the invention and, together with the description, serve to explain the principles of the invention.

FIG. 1 is a sectional view for explaining the schematic structure of an example of a substrate heating apparatus of the present invention;

FIG. 2 is a sectional view for explaining the schematic structure of another embodiment of the substrate heating apparatus shown in FIG. 1;

FIG. 3 is a sectional view for explaining the schematic structure of another embodiment of the substrate heating apparatus shown in FIG. 2;

FIG. 4 is a sectional view for explaining the schematic structure of another example of the substrate heating apparatus of the present invention;

FIG. 5 is a sectional view for explaining the schematic structure of another embodiment of the substrate heating apparatus shown in FIG. 4;

FIG. 6 is a sectional view for explaining the schematic structure of another embodiment of the substrate heating apparatus shown in FIG. 5; and

FIG. 7 is a sectional view for explaining the schematic structure of a conventional substrate heating apparatus.

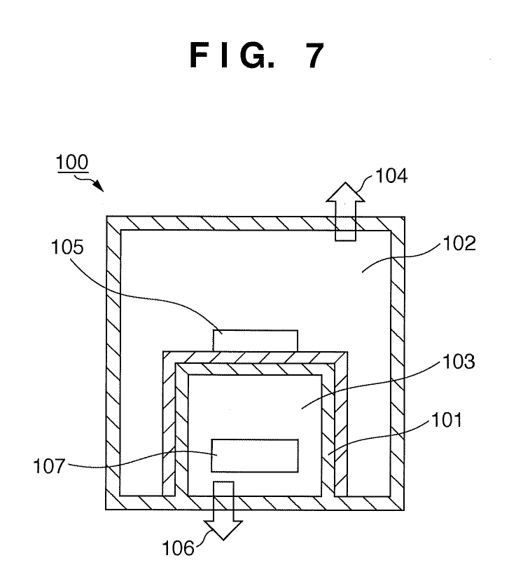

### BEST MODE FOR CARRYING OUT THE INVENTION

Examples of preferred embodiments of the present invention will be described hereinafter in detail with reference to the accompanying drawings. Note that the constituent elements described in the embodiments are merely examples, and that the technical scope of the present invention is determined by the appended claims and not limited by the following specific embodiments.

### First Embodiment

The characteristic feature of the substrate heating apparatus of the present invention resides in that a wall body which separates the interior of a vacuum vessel into a first space which accommodates a substrate to be heated and a second space which accommodates a heating means for heating the substrate has a non-coated exposed graphite portion in a wall body surface which faces the second space.

Coating described above can be performed using pyrolytic carbon or pyrolytic graphite. Silicon carbide (SiC), tantalum carbide (TaC), or the like which is a low-vapor-pressure, refractory compound can be employed. Alternatively, BNC (amorphous B-N-C sputtering film) can be used.

GfG coating can also be employed. To form a GfG coating, graphite undergoes a high purity process, and the resultant porous graphite is impregnated with a resin and baked at 2,000° C. or more to evaporate impurities. Graphite can be coated to a depth of several hundred μm, so that its volume density can be increased from a normal value of 1.87 to 2.21.

A coating formed by one of above schemes is advantageous because it does not sublimate, decompose, or evaporate easily by heating even if the heating means employs one of a heating means for electron impact heating which has an electron-emitting source, a laser heating means, a lamp heating means, and an RF induction heating means, or a combination of arbitrary ones of them.

The interior of the vacuum vessel is separated into the first space and second space by the wall body. The first space is evacuated to a vacuum by a first exhaust means and accommodates a substrate to be heated. The second space is evacuated to a vacuum by a second exhaust means and includes a heating means which heats the substrate accommodated in the first space.

In the internal heating type substrate heating apparatus, the wall body is made of graphite having a high emissivity and high thermal conductivity. Graphite is coated with a coating material so that gas occlusion in the graphite is prevented.

As the substrate heating apparatus is repeatedly used at a high temperature of approximately 2,000° C., microscopic cracks may be formed on the surface of the coating by a heat gradient.

In the present invention, as described above, an exposed graphite portion is formed on the wall body surface which faces the second space, so that the stress existing in the coating is moderated, thus overcoming this problem.

The substrate heating apparatus of the present invention described above can employ, as the heating means, one of a heating means for electron impact heating which has an electron-emitting source, a laser heating means, a lamp heating means, and an RF induction heating means, or a combination of arbitrary ones of them.

Whichever heating means may be employed, desirably, an exposed graphite portion is not formed in a region which is affected by the heat of the heating means directly or actively. If a non-coating surface is formed in the region which is affected by heat of the heating means directly or actively, a component that forms the heating vessel may be emitted into the internal space of the heating vessel due to the influence of the heat. This is not preferable.

For example, when a heating means for electron impact heating which has an electron-emitting source is employed as the heating means, an exposed graphite portion can be formed on a surface, which faces the second space, of the wall body against which electrons emitted by the electron-emitting source do not collide linearly.

If the heating means arranged in the second space is a heating means for electron impact heating which has an electron-emitting source, electrons emitted by the electron-emitting source collide against that surface of the wall body which faces the second space, thus heating the wall body. Then, the substrate arranged in the first space is heated.

If the exposed graphite portion is formed at a position against which electrons emitted by the electron-emitting source collide linearly, the electrons directly collide against graphite that forms the wall body. This is not preferable.

According to the present invention, when the heating means is a heating means for electron impact heating which has an electron-emitting source, the exposed graphite portion described above is formed on a surface, which faces the second space, of the wall body against which electrons emitted by the electron-emitting source do not collide linearly.

For example, in the wall body, a small-diameter cylindrical member with a distal end closed with a top plate is coaxially connected to the distal end of a large-diameter cylindrical member. The heating means is set in the small-diameter cylindrical member. In this case, the position of the exposed graphite portion can be set on that surface of a staircase portion formed on a portion where the large-diameter cylindrical member and small-diameter cylindrical member are connected coaxially, which is on the side where the large-diameter cylindrical member is present.

The exposed graphite portion can include one or a plurality of recesses or grooves formed in that surface of the wall body which faces a space in the second space. In this case as well, electrons emitted by the electron-emitting source of the heating means for electron impact heating which has the electron-emitting source do not collide linearly against the exposed graphite portion.

This is particularly advantageous when the exposed graphite portion includes one or a plurality of recesses or grooves formed in that surface of the wall body which faces a space in the second space, because the area of the exposed graphite portion can be increased without enlarging the region in that surface of the wall body which faces the second space, which is occupied by the exposed graphite portion.

According to another embodiment of the present invention, in a substrate heating apparatus including a vacuum vessel with an interior separated by a wall body into a first space and second space, the first space being evacuated to a vacuum by a first exhaust means and serving to accommodate a substrate to be heated, and the second space being evacuated to a vacuum by a second exhaust means and including a heating means for heating the substrate accommodated in the substrate, an exposed graphite portion can be formed on a wall body surface of the wall body which faces the first space.

More specifically, no exposed graphite portion is present on, of the heating vessel evacuated to a vacuum by the second exhaust means, and preferably constantly evacuated to a vacuum, the wall body surface which faces the second space, and an exposed graphite portion is formed on the wall body surface which faces the first space.

As described above, the substrate heating apparatus of the present invention can employ, as the heating means, one of a heating means for electron impact heating which has an electron-emitting source, a laser heating means, a lamp heating means, and an RF induction heating means, or a combination of arbitrary ones of them.

Whichever heating means may be employed, desirably, no non-coating surface is formed on that surface of the wall body which faces the first space, at a position opposing that portion affected by the heat of the heating means directly or actively, of that surface of the wall body which faces the second space.

If a non-coating surface is formed on a region of that surface of the wall body which faces the first space, at a position opposing that portion affected by the heat of the heating means directly or actively, of that surface of the wall body which faces the second space, a component that forms the wall body is actively emitted into first space due to the influence of the heat. This is not preferable.

For example, when a heating means for electron impact heating which has an electron-emitting source is employed as the heating means, a non-coating surface can be formed on, of the wall body, a portion facing the first space and opposing a portion against which electrons emitted by the electron-emitting source do not collide linearly and which faces the second space.

In the substrate heating apparatus of the present invention described above, the exposed graphite portion can be formed by forming coatings on those surfaces of the wall body which face the first space and second space, respectively, and removing the coating surfaces by cutting or the like.

For example, non-coating surfaces can be formed by, for example, forming coatings on those surfaces of the wall body which face the second space and first space, respectively, by chemical vapor deposition, and chipping, with a file, the coatings on those portions where the non-coating surfaces are to be formed, or forming grooves or holes in the formed coating surfaces.

When forming coatings on those surfaces of the wall body which face the second space and first space, respectively, by chemical vapor deposition, a predetermined jig (e.g., a base) may be abutted against portions where exposed graphite portions are to be formed, and the exposed graphite portions can be formed on those surfaces of the wall body against which the jig has been abutted and face the second space and first space, respectively. A member used to form the exposed graphite portions is not limited to a jig. For example, a member that locally covers the surface of the wall body can be used when forming the coatings by chemical vapor deposition. By changing the positions and number of members that locally cover the surface of the wall body, a desired number of exposed graphite portions can be formed at desired positions of the surface of the wall body.

Furthermore, the present invention provides a processing method which uses the substrate heating apparatus.

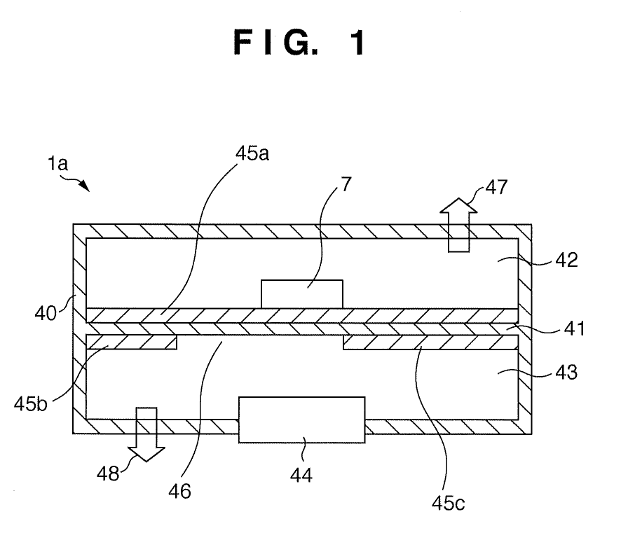

FIG. 1 is a sectional view for explaining the schematic structure of an example of the substrate heating apparatus of the present invention.

An internal heating type substrate heating apparatus 1a includes a vacuum vessel 40 with an interior separated by a wall body 41 into a first space 42 and second space 43.

The first space 42 is evacuated to a vacuum by a first exhaust means (not shown) as indicated by an arrow 47. A substrate 7 to be heated is loaded into and unloaded from the first space 42 by a substrate transport means (not shown) and accommodated in the first space 42 as shown in FIG. 1. The second space 43 is evacuated to a vacuum by a second exhaust means (not shown) as indicated by an arrow 48 and includes a heating means 44 for heating the substrate 7 accommodated in the first space 42.

The wall body 41 is made of graphite having a high emissivity and high thermal conductivity.

A coating 45a is formed on that surface of the wall body 41 which faces the first space 42 where the substrate 7 to be heated is placed.

Coatings 45b and 45c are formed on that surface of the wall body 41 which faces the second space 43 where the heating means 44 is provided. A non-coated exposed graphite portion 46 is formed on part of that surface of the wall body 41 which faces the second space 43.

The coatings 45a, 45b, and 45c are formed for preventing gas occlusion in the wall body 41 made of porous graphite. When the heating means 44 is a heating means for electron impact heating which has an electron-emitting source, the coatings 45a, 45b, and 45c also serve to moderate electron impact.

In the embodiment shown in FIG. 1, the coatings 45a, 45b, and 45c are made of pyrolytic carbon.

The vacuum vessel 40 can include, for example, an aluminum or stainless steel vessel provided with a water-cooling device (not shown) around it.

The substrate 7 as a heating target is heated by evacuating the first space 42 to a vacuum by the first exhaust means (not shown) as indicated by the arrow 47.

The second space 43 where the heating means 44 is arranged is evacuated to a vacuum by the second exhaust means (not shown) as indicated by the arrow 48. Desirably, the second space 43 is constantly evacuated to a vacuum by the second exhaust means (not shown).

When loading and unloading the substrate 7, the first space 42 is set under an atmospheric pressure. When the substrate heating apparatus 1a is repeatedly used over a long period of time, microscopic cracks may be formed in the coatings on the surface that faces the second space 43 where the heating means 44 is arranged.

In the substrate heating apparatus 1a of the present invention, since the exposed graphite portion 46 is formed as described above, the stress existing in the film of the coating 45b or 45c is moderated, so that microscopic cracks which may deteriorate the coating can be prevented.

The exposed graphite portion 46 is desirably formed to have an area of at least 1 cm² or more.

The coatings 45a, 45b, and 45c are formed on the surfaces of the wall body 41 using pyrolytic carbon or the like in accordance with chemical vapor deposition by supporting the wall body 41 with a pin-like jig. An exposed graphite portion with a size approximately equal to the area of the distal end of the pin may also be formed conventionally on that surface of the wall body 41 which faces the second space 43.

The area where the exposed graphite portion 46 is to be formed is desirably 1 cm² or more, which is sufficiently larger than the conventional size (approximately 0.25 cm²) that is almost equal to the area of the distal end of the pin.

In the substrate heating apparatus 1a of the present invention, by forming the exposed graphite portion 46, the stress existing in the coating can be moderated. Thus, microscopic cracks can be prevented, and deterioration of the coating can be prevented.

### Second Embodiment

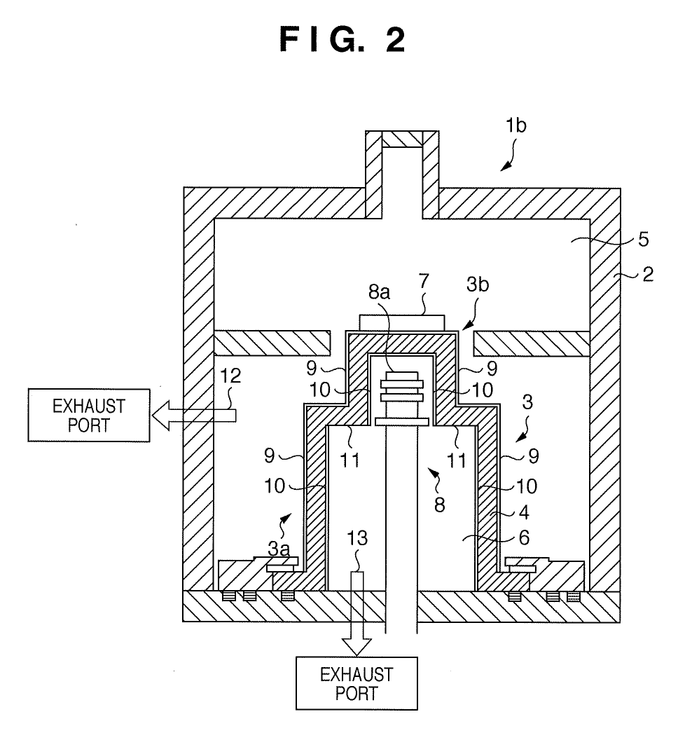

In a substrate heating apparatus 1b shown in FIG. 2, a heating vessel 3 is formed of the wall body 41 of the substrate heating apparatus 1a shown in FIG. 1.

The substrate heating apparatus 1b shown in FIG. 2 includes a vacuum vessel 2 and the heating vessel 3 arranged inside the vacuum vessel 2. A wall body 4 which forms the heating vessel 3 partitions the internal space of the vacuum vessel 2 into a first space 5 and second space 6.

A substrate 7 to be heated is arranged in the first space 5 by a loading/unloading means (not shown). A heating means 8 for heating the substrate 7 is arranged in the second space 6.

Although not shown, the substrate heating apparatus 1b is provided with a first exhaust means for evacuating the first space 5 to a vacuum as indicated by an arrow 12 and a second exhaust means for evacuating the second space 6 to a vacuum as indicated by an arrow 13.

The wall body 4 which forms the heating vessel 3 is made of graphite 7 having a high emissivity and high thermal conductivity, in the same manner as the wall body 41 of the first embodiment.

A coating 9 is formed on the outer surface of the wall body 4, that is, on that surface of the wall body 4 which faces the first space 5. A coating 10 is formed on the inner surface of the wall body 4, that is, on that surface of the wall body 4 which faces the second space 6.

In the arrangement of the substrate heating apparatus 1b shown in FIG. 2, the coatings 9 and 10 are made of pyrolytic carbon.

The substrate heating apparatus 1b is used for heating to a high temperature, for example, silicon carbide (SiC) which attracts attention as a next-generation semiconductor power device material, that is, an SiC activation annealing apparatus (EBAS apparatus). In the EBAS apparatus, nitrogen ions are injected onto an SiC substrate, and the substrate is heated to a high temperature close to 2,000° C.

For example, the vacuum vessel 2 can include an aluminum or stainless steel vessel provided with a water-cooling device (not shown) around it.

The substrate 7 as a heating target is heated by evacuating the first space 5 to a vacuum by the first exhaust means (not shown) as indicated by the arrow 12.

The second space 6 provided with the heating means 8 is evacuated to a vacuum by the second exhaust means (not shown) as indicated by the arrow 13. Desirably, the second space 6 is constantly evacuated to a vacuum by the second exhaust means (not shown).

In the embodiment shown in FIG. 2, the wall body 4 which forms the heating vessel 3 has the following structure. A small-diameter cylindrical member 3b with a distal end closed with a top plate is coaxially connected to the distal end of a large-diameter cylindrical member 3a. The heating means 8 is set in the small-diameter cylindrical member 3b.

That surface of a staircase portion formed on a portion where the large-diameter cylindrical member 3a and small-diameter cylindrical member 3b are connected coaxially, on the side where the large-diameter cylindrical member 3a is present, forms an exposed graphite portion 11 having no coating 10.

In this manner, in the embodiment shown in FIG. 2 as well, in the same manner as in the embodiment shown in FIG. 1, the coating 9 is formed on that surface of the wall body 4 which faces the first space 5 where the substrate 7 to be heated is placed. Also, the coating 10 is formed on that surface of the wall body 4 which faces the second space 6 where the heating means 8 is provided. The non-coated exposed graphite portion 11 is formed on part of that surface of the wall body 4 which faces the second space 6.

When unloading or loading the substrate 7 from or into the first space 5, the first space 5 is set under the atmospheric pressure.

When the substrate heating apparatus 1b is repeatedly used over a long period of time, microscopic cracks may be formed in the coating 10 on the outer surface of the heating vessel 3, starting from a portion having a large heat gradient.

In the substrate heating apparatus 1b of the present invention, the stress existing in the coating is moderated by forming the exposed graphite portion 11. Thus, microscopic cracks can be prevented, and deterioration of the coating can be prevented.

An example of a processing method of heating the substrate 7 by the substrate heating apparatus 1b of the embodiment shown in FIG. 2 will now be schematically described.

The first space 5 is set at an atmospheric pressure state. The substrate 7 as the heating target is loaded in the first space 5 and set on the top plate of the small-diameter cylindrical member 3b which forms the heating vessel 3 (substrate loading step).

Even during this step, the second space 6 in the heating vessel 3 is kept evacuated to a vacuum by the second exhaust means (not shown) as indicated by the arrow 13 (vacuum evacuating step of the second space).

Subsequently, the first space 5 is evacuated to a vacuum by the first exhaust means (not shown) as indicated by the arrow 12 until reaching a vacuum degree required for substrate heating (vacuum evacuating step of the first space).

After the first space 5 reaches a predetermined vacuum degree in this manner, nitrogen ions are injected into the first space 5 by an ion injecting means (not shown) (ion injecting step). A high voltage is applied to the heating means 8 arranged in the second space 6 in the heating vessel 3 (high-voltage applying step) and causes an electron-emitting source 8a to generate thermoelectrons. The inner surface of the heating vessel 3 is thus heated by electron impact, so that the substrate 7 is heated at a high temperature of approximately 2,000° C. (heating step).

After the substrate 7 is heated, the heated substrate 7 is unloaded from the first space 5 (substrate unloading step). To load another substrate 7 to be heated, the first space 5 is opened again and set in the atmospheric pressure state.

Even during the exchange of the substrates 7, the second space 6 in the heating vessel 3 is kept evacuated to a vacuum by the second exhaust means (not shown) as indicated by the arrow 13.

As described above, substrate heating is performed at the high temperature of about 2,000° C. When exchanging the substrates 7, the first space 5 is opened and set in the atmospheric pressure state. After that, the step of vacuum evacuation is repeated a number of times until reaching the vacuum degree required for heating the substrate.

In the embodiment shown in FIG. 2, the large-diameter cylindrical member 3a and small-diameter cylindrical member 3b are coaxially connected to form the staircase portion (step portion). The exposed graphite portion 11 covers the entire surface of the step portion which faces the second space in the large-diameter cylindrical member 3a.

Desirably, the exposed graphite portion 11 is formed to have an area of at least 1 cm² or more, in the same manner as in the first embodiment described above.

In the embodiment shown in FIG. 2, the exposed graphite portion 11 is formed on the step portion which faces the second space in the large-diameter cylindrical member 3a. However, the position to form the exposed graphite portion 11 is not limited to the position illustrated in FIG. 2.

When a heating means for electron impact heating which has the electron-emitting source 8a is employed as the heating means 8, it is not desirable if electrons emitted by the electron-emitting source 8a collide linearly against the exposed graphite portion 11 and thus against the non-coated graphite wall body 4. In view of this, when a heating means for electron impact heating which has the electron-emitting source 8a is employed as the heating means 8, desirably, the exposed graphite portion 11 is formed at a position against which the electrons emitted from the electron-emitting source 8a do not collide linearly.

In the embodiment shown in FIG. 2, the heating vessel 3 has a structure in which the small-diameter cylindrical member 3b is coaxially connected to the large-diameter cylindrical member 3a. The heating means 8 is set in the small-diameter cylindrical member 3b. The heating vessel of this form is suitable to an EBAS apparatus. In this case, the exposed graphite portion 11 is formed at the step portion which faces the second space in the large-diameter cylindrical member 3a, and the heating means 8 is set in the small-diameter cylindrical member 3b. Thus, the electrons emitted by the electron-emitting source 8a do not collide linearly against the exposed graphite portion 11.

In the case of the heating vessel suitable to the EBAS apparatus, as shown in FIG. 2, generally, the coatings 9 and 10 of the graphite wall body 4 which forms the heating vessel 3 are formed by chemical vapor deposition while supporting the heating vessel 3 with a predetermined jig (e.g., a base). When forming the exposed graphite portion 11 at a staircase portion as shown in FIG. 2, the surface of the staircase portion (step portion) may be covered while supporting this portion by a jig, and in this state the coating 10 may be formed inside the large-diameter cylindrical member 3a. This is advantageous because the exposed graphite portion 11 having a desired area can be easily formed by adjusting the area where the jig is in contact with the staircase portion.

Even when the electron-emitting source 8a is employed as the heating means 8, if the exposed graphite portion 11 is formed at a position against which the electrons emitted by the electron-emitting source 8a will not collide linearly, electron collision against the non-coated graphite wall body 4 can be prevented. Therefore, as far as this purpose is achieved, the exposed graphite portion 11 need not always be formed at the staircase portion (step portion) as shown in FIG. 2.

Alternatively, considering the shape and structure of the wall body 41 in the substrate heating apparatus 1a according to the first embodiment shown in FIG. 1 and the shape and structure of the heating vessel 3 formed of the wall body 4 in the substrate heating apparatus 1b according to the second embodiment shown in FIG. 2, the exposed graphite portion 46 or 11 can be formed on that surface of the wall body 41 or 4 which faces the second space 6, at a portion of the wall body 41 or 4 that may occlude the gas highly possibly.

### Third Embodiment

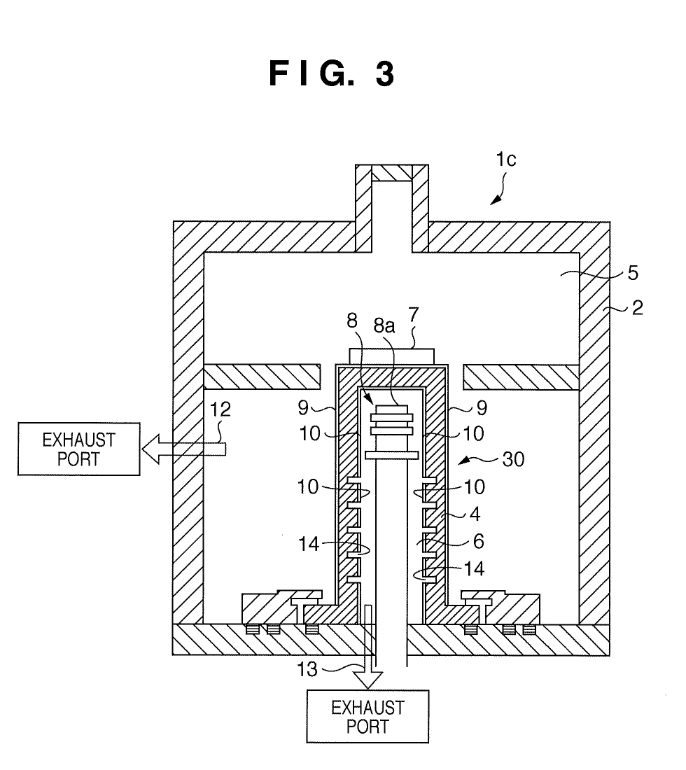

FIG. 3 is a view showing an arrangement of a substrate heating apparatus 1c according to the third embodiment of the present invention, and describes another embodiment of the substrate heating apparatus 1b shown in FIG. 2.

The same constituent members as those shown in FIG. 2 and described in the second embodiment are denoted by the same reference numerals as in FIG. 2, and a repetitive description will be omitted.

The substrate heating apparatus 1c shown in FIG. 3 is different from the substrate heating apparatus 1b shown in FIG. 2 in that a heating vessel 30 is formed of a cylinder having one diameter and that grooves 14 are formed in the inner surface of a graphite wall body 4 which forms the heating vessel 30 and serve as the exposed graphite portion.

Coatings 9 and 10 made of a coating material such as pyrolytic carbon are formed on the inner and outer surfaces of the graphite wall body 4 which forms the heating vessel 11, in the same manner as in the substrate heating apparatus 1 shown in FIG. 2. An electron-emitting source 8a serving as a heating means 8 is set at an upper portion in the heating vessel 30.

In the third embodiment shown in FIG. 3, the grooves 14 are formed by notching the graphite wall body 4 which forms the heating vessel 30 in the direction of thickness. For example, the grooves 14 can be formed in the inner wall of the cylindrical wall body 4 to each have approximately a width of 5 mm and a depth of 1 mm. In FIG. 3, the grooves 14 include a plurality of (five) grooves at predetermined gaps in the vertical direction. One or a plurality of grooves 14 may be formed by considering the vacuum evacuation speed and the like.

Although not shown, in place of the grooves 14, for example, one or a plurality of recesses such as holes each having approximately a diameter of 5 mm and a depth of 1 mm may be formed in the inner wall of the cylindrical wall body 4 by considering the vacuum evacuation speed and the like.

In the embodiment shown in FIG. 3, the grooves or recesses formed in the inner wall of the graphite wall body 4 which forms the heating vessel 30 serve as the exposed graphite portion. Even when the electron-emitting source 8a is employed as the heating means 8, electrons emitted by the electron-emitting source 8a will not linearly collide against the exposed graphite portion.

If one or the plurality of recesses or grooves 14 formed in the inner wall of the graphite wall body 4 which forms the heating vessel 30 serve as the exposed graphite portion, as in the embodiment shown in FIG. 3, the area of the exposed graphite portion can be increased without increasing the region of the inner surface of the heating vessel 30 which is occupied by the exposed graphite portion.

### Fourth Embodiment

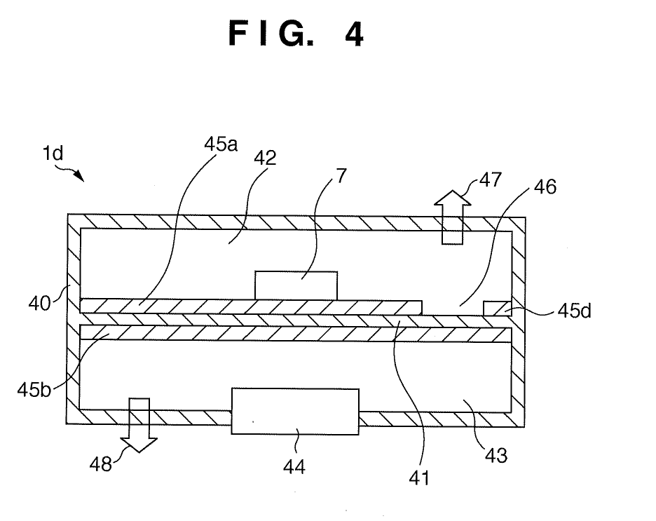

FIG. 4 is a view showing an arrangement of a substrate heating apparatus 1d according to the fourth embodiment of the present invention, and shows another embodiment of the substrate heating apparatus 1a of the first embodiment described with reference to FIG. 1.

The same constituent members as those shown in FIG. 1 and described in the first embodiment are denoted by the same reference numerals as in FIG. 1, and a repetitive description will be omitted.

In the substrate heating apparatus 1a shown in FIG. 1, the coating 45a is formed on that entire surface of the wall body 41 which faces the first space 42 where the substrate 7 to be heated is placed. The coatings 45b and 45c are formed on that surface of the wall body 41 which faces the second space 43 where the heating means 44 is arranged. The non-coated exposed graphite portion 46 is formed on part of the surface of the wall body 41 which faces the second space 42.

In the substrate heating apparatus 1d shown in FIG. 4, a coating 45b is formed on that entire surface of a wall body 41 which faces a second space 43 where a heating means 44 is arranged. Also, coatings 45a and 45d are formed on that surface of the wall body 41 which faces a first space 42 where a substrate 7 to be heated is placed. A non-coated exposed graphite portion 46 is formed on part of that surface of the wall body 41 which faces the first space 42.

This arrangement can moderate the stress. As a result, microscopic cracks will not be formed and the deterioration of the coating can be maintained, so that the structural stability of the wall body can be maintained.

### Fifth Embodiment

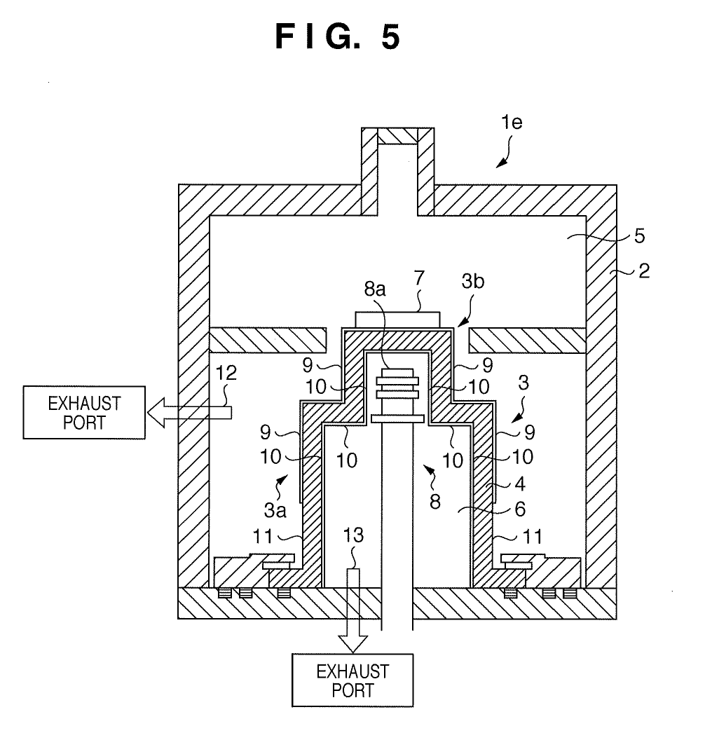

FIG. 5 is a view showing an arrangement of a substrate heating apparatus 1e according to the fifth embodiment of the present invention. An exposed graphite portion 11 is formed on a wall surface 4 of a heating vessel 3, on the side of a first space where a substrate 7 is held, in the same manner as the wall body 41 of the substrate heating apparatus 1d shown in FIG. 4. The arrangement of the substrate heating apparatus 1e shown in FIG. 5 corresponds to the substrate heating apparatus 1b of the second embodiment described with reference to FIG. 2.

The same constituent members as those shown in FIG. 2 and described in the second embodiment are denoted by the same reference numerals as in FIG. 2, and a repetitive description will be omitted.

The substrate heating apparatus 1e shown in FIG. 5 is different from the substrate heating apparatus 1b shown in FIG. 2 in that a coating 10 is formed to cover the entire inner surface of a large-diameter cylindrical member 3a and the entire inner surface of a small-diameter cylindrical member 3b which form the heating vessel 3, and that the exposed graphite portion 11 is formed on the outer surface of the large-diameter cylindrical member 3a.

The outer surface of the large-diameter cylindrical member 3a where the exposed graphite portion 11 is formed is the outer surface of the large-diameter cylindrical member 3a which opposes the inner surface of the large-diameter cylindrical member 3a against which electrons emitted by an electron-emitting source 8a do not collide linearly.

In the substrate heating apparatus 1e shown in FIG. 5, when loading/unloading the substrate 7 to be heated, a first space 5 is roughly evacuated by a first exhaust means (not shown). This rough evacuation evacuates a large quantity of gas.

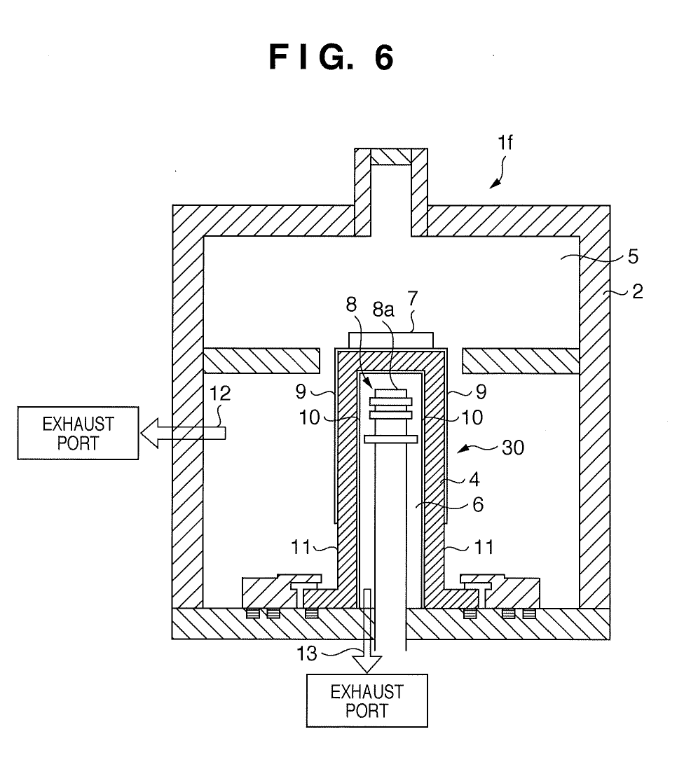

A heating vessel 30 can also be formed of a cylinder having one diameter, as shown in FIG. 6.

Preferred embodiments of the present invention have been described so far with reference to the accompanying drawings. Note that the present invention is not limited to these embodiments, but can be modified in various modes within a technical scope grasped from the appended claims.

The present invention is not limited to the above embodiments and various changes and modifications can be made without departing from the spirit and scope of the present invention. Therefore, to apprise the public of the scope of the present invention, the following claims are appended.

This application claims the benefit of Japanese Patent Application No. 2007-072960, filed Mar. 20, 2007, which is hereby incorporated by reference herein in its entirety.

1. A substrate heating apparatus for heating a substrate, comprising:
a vacuum vessel with an interior separated by a wall body made of graphite with a surface coated with a coating material including a carbon atom into a first space which accommodates a substrate to be heated and a second space where heating means for heating the substrate accommodated in the first space is arranged,
wherein the wall body facing the second space includes a portion in which coating is formed on a surface of the wall body, and an exposed graphite portion in which coating is not formed on a surface of the wall body.

2. The substrate heating apparatus according to claim 1, wherein
the heating means comprises heating means for electron impact heating which includes an electron-emitting source, and
the exposed graphite portion is formed on a wall body surface, which faces the second space, of the wall body against which electrons emitted by the electron-emitting source do not collide linearly.

3. The substrate heating apparatus according to claim 1, wherein
the wall body is obtained by coaxially connecting a small-diameter cylindrical member with a distal end closed with a top plate to a distal end of a large-diameter cylindrical member, and
the heating means is set in the small-diameter cylindrical member, and the exposed graphite portion is formed on, of a staircase portion formed on a portion where the large-diameter cylindrical member and the small-diameter cylindrical member are connected coaxially, a portion which faces the second space in the large-diameter cylindrical member.

4. The substrate heating apparatus according to claim 1, wherein the exposed graphite portion comprises one or a plurality of recesses or grooves formed in a portion of the wall body which faces the second space.

5. A substrate heating apparatus for heating a substrate, comprising:
a vacuum vessel with an interior separated by a wall body made of graphite with a surface coated with a coating material including a carbon atom into a first space which accommodates a substrate to be heated and a second space where heating means for heating the substrate accommodated in the first space is arranged,
wherein the wall body facing the first space includes an exposed graphite portion on a surface of the wall body.

6. The substrate heating apparatus according to claim 5, wherein
the heating means comprises heating means for electron impact heating which includes an electron-emitting source, and
the exposed graphite portion is formed on, of the wall body, a portion facing the first space and opposing a portion against which electrons emitted by the electron-emitting source do not collide linearly and which faces the second space.

7. The substrate heating apparatus according to claim 1, wherein coating by using the coating material including the carbon atom comprises coating using any one of pyrolytic carbon, silicon carbide (SIC), tantalum carbide (TaC), and BNC, or GfG coating.

8. A substrate heating method of heating a substrate using a substrate heating apparatus according to claim 1.

9. The substrate heating method according to claim 8, wherein the substrate is made of a silicon carbide (SiC) for a semiconductor device.
